(19) United States
(12) Patent Application Publication
(10) Pub. No.: US 2006/0195765 A1
(43) Pub. Date: Aug. 31, 2006

(54) Accelerating convergence in an iterative decoder

(75) Inventor: John T. Coffey, San Francisco, CA (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/068,256

(22) Filed: Feb. 28, 2005

(51) Int. Cl. H03M 13/00

(52) U.S. Cl. 714/760

(57) ABSTRACT

An iterative forward error control code (FECC) decoder (28; 28′) is disclosed. The decoder (28; 28′) operates by adjusting probability values for codeword bits at a selected iteration in the decoding sequence. According to one disclosed embodiment, those probability values that are above a certain threshold value prior to one of the last decoding iterations are adjusted to a full reliability value. According to other disclosed embodiments, a linear or non-linear adjustment function is applied. The decoder may be a turbo decoder, a Low Density Parity Check (LDPC) decoder, or a decoder for any FECC code for which iterative decoding is appropriate.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

This invention is in the field of digital data communications, and is more specifically directed to decoding of transmissions that have been coded for error detection and correction.

High-speed data communications, for example in providing high-speed Internet access, is now a widespread utility for many businesses, schools, and homes. At this stage of development, such access is provided according to an array of technologies. Data communications are carried out over existing telephone lines, with relatively slow data rates provided by voice band modems (e.g., according to the current v.92 communications standards), and at higher data rates using Digital Subscriber Line (DSL) technology. Another modern data communications approach involves the use of cable modems communicating over coaxial cable, such as provided in connection with cable television services. The Integrated Services Digital Network (ISDN) is a system of digital phone connections over which data is transmitted simultaneously across the world using end-to-end digital connectivity. Localized wireless network connectivity according to the IEEE 802.11 standard has become very popular for connecting computer workstations and portable computers to a local area network (LAN), and often through the LAN to the Internet. Wireless data communication in the Wide Area Network (WAN) context, which provides cellular-type connectivity for portable and handheld computing devices, is expected to also grow in popularity.

A problem that is common to all data communications technologies is the corruption of data due to noise. As is fundamental in the art, the signal-to-noise ratio for a communications channel is a degree of goodness of the communications carried out over that channel, as it conveys the relative strength of the signal that carries the data (as attenuated over distance and time), to the noise present on that channel. These factors relate directly to the likelihood that a data bit or symbol received over the channel is in error relative to the data bit or symbol as transmitted. This likelihood is reflected by the error probability for the communications over the channel, commonly expressed as the Bit Error Rate (BER) ratio of errored bits to total bits transmitted. In short, the likelihood of error in data communications must be considered in developing a communications technology. Techniques for detecting and correcting errors in the communicated data are commonly incorporated to render the communications technology useful.

Error detection and correction techniques are typically implemented through the use of redundant coding of the data. In general, redundant coding inserts bits into the transmitted data stream that do not add any additional information, but that instead depend on combinations of the already-present data bits. This procedure adds patterns that can be exploited by the decoder to determine whether an error is present in the received data stream. More complex codes provide the ability to deduce the true transmitted data from a received data stream, despite the presence of errors.

Many types of redundant codes that provide error correction have been developed. One type of code simply repeats the transmission, for example repeating the payload twice, so that the receiver deduces the transmitted data by applying a decoder that determines the majority vote of the three transmissions for each bit. Of course, this simple redundant approach does not necessarily correct every error, but greatly reduces the payload data rate, defined as the ratio of the number of data bits to the overall number of bits (data bits plus redundant bits). In this example, a predictable likelihood remains that two of three bits are in error, resulting in an erroneous majority vote despite the useful data rate having been reduced to one-third. More efficient approaches, such as Hamming codes, have been developed toward the goal of reducing the error rate while maximizing the data rate.

The well-known Shannon limit provides a theoretical bound on the optimization of decoder error as a function of data rate. The Shannon limit provides a metric against which codes can be compared, both in the absolute and relative to one another. Since the time of the Shannon proof, modem data correction codes have been developed to more closely approach the theoretical limit.

One important type of these conventional codes are “turbo” codes, which encode the data stream by applying two convolutional encoders. One convolutional encoder encodes the datastream as given, while the other encodes a pseudo-randomly interleaved version of the data stream. The results from the two encoders are interwoven (concatenated), either serially or in parallel, to produce the output encoded data stream. Turbo coding involving parallel concatenation is often referred to as a parallel concatenated convolutional code (PCCC), while serial concatenation results in a serial concatenated convolutional code (SCCC). Upon receipt, turbo decoding involves first decoding the received sequence according to one of the convolutional codes, de-interleaving the result, then applying a second decoding according to the other convolutional code, and repeating this process multiple times.

Another class of known redundant codes are the Low Density Parity Check (LDPC) codes. According to this approach, a relatively sparse code matrix is defined, such that the product of this matrix with each valid codeword (information and parity bits) equals the zero matrix. Decoding of an LDPC coded message to which channel noise has been added in transmission amounts to finding the sparsest vector that, when used to multiply the sparse code matrix, matches the received sequence. This sparsest vector is thus equal to the channel noise (because the matrix multiplied by the true codeword is zero), and can be subtracted from the received sequence to recover the true codeword.

It has become well known in the art that iterative decoding approaches provide excellent decoding performance, from the standpoint of latency and accuracy, with relatively low hardware or software complexity. Iterative approaches are also quite compatible with turbo codes, LDPC codes, and many other FECC codes known in the art.

Typically, iterative decoding involves the communicating, or “passing”, of reliability, or “soft output”, values of the codeword bits over several iterations of a relatively simple decoding process. Soft output information includes, for each bit, a suspected value of the bit (“0” or “1”), and an indication of the probability that the suspected value is actually correct. In many cases, this information is conveyed in the form of a log-likelihood-ratio (LLR), typically defined as:

$$L ( c ) = log ( \frac{P ( c = 0 )}{P ( c = 1 )} )$$

where P(c=0) is the probability that codeword bit c truly has a zero value, and thus where P(c=1) is the probability that codeword bit c is truly a one. In this case, the sign of the LLR L(c) indicates the suspected binary value (negative values indicating a higher likelihood that bit c is a 1), and the magnitude communicates the probability of that suspected result.

FIG. 1 illustrates the data flow in a conventional turbo decoder, in an iterative configuration. The inputs to this turbo decoder include first and second inputs INPUT_1, INPUT_2, respectively, which correspond to the two encodings of a given block of data that are concatenated for transmission. These two encodings INPUT_1, INPUT_2 are separated at the receiver end, prior to applying to the turbo decoder of FIG. 1. The first encoding INPUT_1 is applied to an input of first decoder 2, while the second encoding INPUT_2 is applied to an input of second decoder 6, as shown. First decoder 2 is typically an approximation to a maximum a posteriori (MAP) decoder. First decoder 2 generates a set of a posteriori probabilities Λ₁ (typically expressed as LLRs) for each of the bits of the codeword, using the first encoding input INPUT_1 in combination with a priori probabilities for these bits as generated by second decoder 6 (as will be described below). For the initial decoding of an incoming input, these a priori probabilities are simply initialized to a neutral value (i.e., no knowledge of their likelihood).

At summer 3, a priori probabilities are subtracted from the a posteriori output probabilities Λ₁ from first decoder 2, to reduce the positive feedback effect of the a priori probabilities on downstream calculations, as is well known. The resulting probabilities N₁ are then interleaved by interleaver 4, to align the codeword bits into the same interleaved order as used in the turbo encoding. These interleaved probabilities N₁ are then applied to second decoder 6, as a priori probabilities to be used in its decoding of second encoding INPUT_2. The output of second decoder is a sequence of a posteriori probabilities Λ₂. The interleaved a priori probabilities used by second decoder 6 are subtracted from these probabilities Λ₂, at summer 7, to produce a corresponding set of probabilities N₂. These probabilities N₂ are de-interleaved by de-interleaver 8 to produce the a priori probabilities applied to first decoder 2, as discussed above.

The decoding illustrated in FIG. 1 continues for a number of iterations, until some termination criterion is reached. Termination of the iterations may be based on a data-dependent convergence criterion. For example, the iterations may continue until there are no bit changes from one iteration to the next, at which point convergence may be assumed because the codeword bits will then tend to reinforce their probabilities. Typically, conventional communications equipment instead performs a preselected number of iterations without regard to the results, with the number of iterations selected by way of experimentation or characterization. In any case, upon reaching the termination criterion, the a posteriori probabilities Λ₂ are applied to function 9, which de-interleaves the probabilities Λ₂ into the original order, and converts the probabilities Λ₂ into “hard” decision bits (binary levels), constructing the decoded codeword C.

FIG. 2 schematically illustrates the iterative operation of a “belief propagation” approach to LDPC decoding. In its conventional implementation, the belief propagation algorithm uses two value arrays, a first array 13 storing the LLRs for each of j input nodes corresponding to the bits in the codeword; this array 13 is also referred to in the art as the array of “variable” nodes. A second array 15 stores the results of m parity check node updates; this array 15 is also referred to as the array of “checksum” nodes. The values m and j typically differ from one another; with typically many more codeword bits j than there are checksum equations m. The LDPC codes are typically characterized by the degree distribution pair (λ, p), where each variable node presents its LLR value to λ checksum equations, and where each checksum node receives ρ LLR values.

Information is communicated back and forth between the variable nodes 13 and the checksum nodes 15 in each iteration of this LDPC belief propagation approach (also referred to as “message passing”). In its general operation, in a first decoding step, each of the variable nodes 13 communicate the current LLR value for its codeword bit to each of the checksum nodes 15 that it participates in. Each of the checksum nodes 15 then derives a check node update for each LLR value that it receives, using the LLRs for each of the other variable nodes 13 participating in its equation. As mentioned above, the parity check equation for LDPC codes requires that the product of the parity matrix with a valid codeword is zero. Accordingly, for each variable node 13, checksum node 15 determines the likelihood of the value of that input that will produce a zero-valued product; for example, if the five other inputs to a checksum node 15 that receives six inputs are strongly likely to be a “1”, it is highly likely that the variable node 13 under analysis is also a “1” (to produce a zero value for that matrix row). The result of this operation is then communicated from checksum nodes 15 to its participating variable nodes 13. In the second decoding step, the variable nodes 13 updates its LLR probability value by combining, for its codeword bit, the results for that variable node 13 from each of the checksums 15 in which that input node participated. This two-step iterative approach is repeated a convergence criterion is reached, or until a terminal number of iterations have been executed.

As known in the art, other iterative coding and decoding approaches are known. But in general, each of these iterative decoding approaches generate an output that indicates the likely data value of each codeword bit, and also indicates a measure of confidence in that value for that bit (i.e., probability).

As mentioned above, iterative decoders can provide excellent performance at reasonable complexity from a circuit or software standpoint. However, the decoding delay, or latency, depends strongly on the number of decoding iterations that are performed. It is known, particularly for parallel concatenated convolutional codes (PCCCs), that this latency may be reduced by parallelizing the decoding functions. For an example of a two-stage decoder (as in FIG. 1) requiring five iterations, it is possible to implement ten actual binary convolutional code decoders, each of which operates on one-tenth of the Viterbi trellis for the decoding. It has been observed that such parallelization can provide essentially no performance loss, while greatly reducing the decoding latency in the system. However, the hardware required for such parallelization is substantial (e.g., 10× for this five iteration example).

Accordingly, the architects of decoding systems are faced with optimizing a tradeoff among the factors of decoding performance (bit error rate), decoding latency or delay, and decoder complexity. The number of iterations is typically determined by the desired decoder performance, following which one may trade off decoding delay against circuit complexity, for example by selecting a parallelization factor. Conversely, defining a given decoding delay and decoder complexity will essentially determine the maximum code performance.

### BRIEF SUMMARY OF THE INVENTION

It is therefore an object of this invention to provide an architecture for an iterative decoder in which the tradeoffs among delay and complexity are significantly eased without severely impacting code performance.

It is a further object of this invention to provide such an architecture that can be efficiently implemented into existing hardware solutions.

It is a further object of this invention to provide such an architecture in which a wide range of flexibility in code performance can be easily realized.

Other objects and advantages of this invention will be apparent to those of ordinary skill in the art having reference to the following specification together with its drawings.

The present invention may be implemented into an iterative decoder by providing a computational point in the decoding immediately before a known number of iterations from the terminal condition. At this computational point, the probabilities for one or more codeword bits are adjusted, preferably based on the assumption that their corresponding codeword bit will not change state in the remaining iterations. The adjusted probabilities will accelerate the convergence of other codeword bits to likely results, reducing the decoding latency without impacting code performance.

### BRIEF DESCRIPTION OF THE SEVERAL VIEWS OF THE DRAWING

FIG. 1 is a data flow diagram illustrating the operation of a conventional turbo decoder.

FIG. 2 is a bipartite data flow diagram illustrating the operation of conventional LDPC message passing decoding.

FIG. 3 is a data flow diagram illustrating a communications system constructed according to the preferred embodiments of the invention.

FIG. 4 is an electrical diagram, in block form, of an example of a receiving transceiver in the system of FIG. 3, constructed according to the preferred embodiments of the invention.

FIG. 5 is a flow chart illustrating the operation of the preferred embodiments of the invention in connection with a generalized decoding process.

FIG. 6 is a data flow diagram illustrating the operation of a turbo decoder according to the preferred embodiments of the invention.

FIGS. 7a through 7c are plots illustrating adjustments of codeword bit probabilities according to alternative preferred embodiments of the invention.

### DETAILED DESCRIPTION OF THE INVENTION

The present invention will be described in connection with its preferred embodiment, namely as implemented into digital circuitry in a communications receiver, such as a wireless network adapter according to the IEEE 802.11a wireless standard in which the binary convolutional code prescribed by that standard is replaced by a turbo code or LDPC code. However, as will be apparent to those skilled in the art, this invention will be beneficial in a wide range of applications, indeed in any application in which received coded information is to be decoded. Examples of such applications include wireless telephone handsets, broadband modulator/demodulators (“modems”), network elements such as routers and bridges in optical and wired networks, and even including data transfer systems such as disk drive controllers within a computer or workstation. Accordingly, it is to be understood that the following description is provided by way of example only, and is not intended to limit the true scope of this invention as claimed.

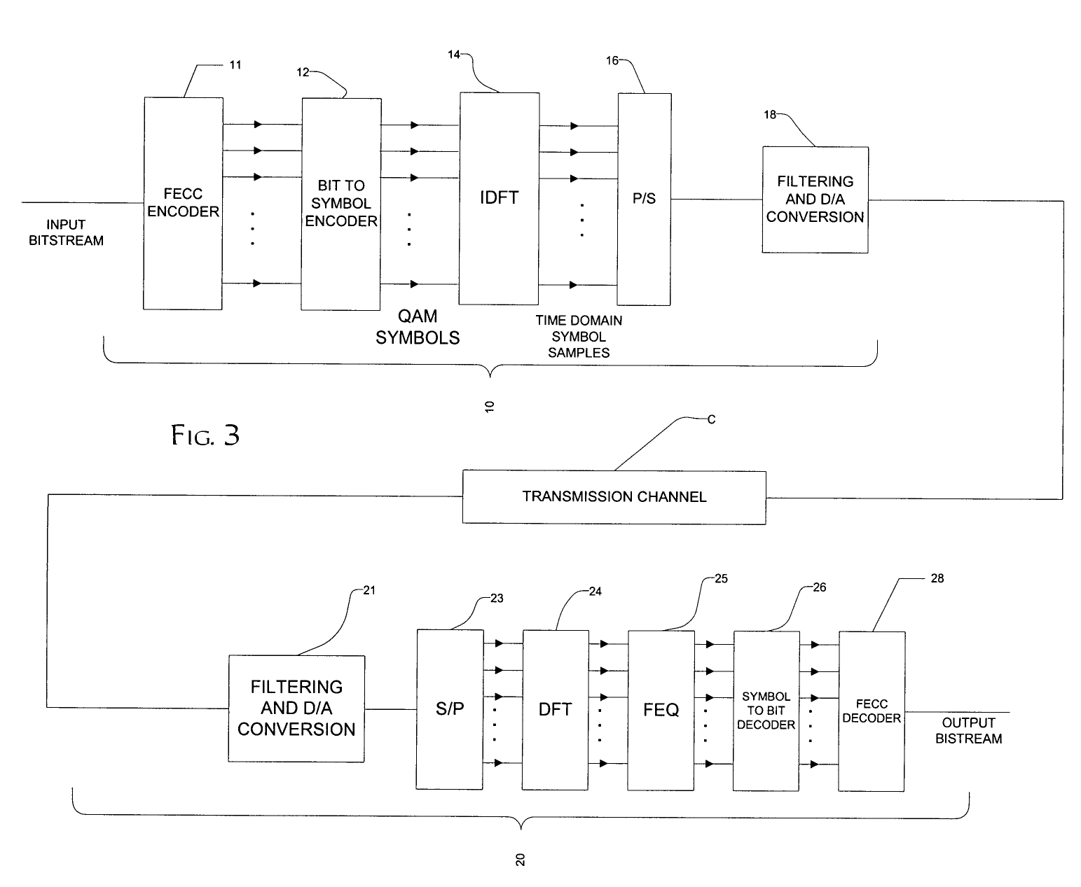

FIG. 3 functionally illustrates an example of a somewhat generalized communication system into which the preferred embodiment of the invention is implemented. The illustrated system corresponds to an OFDM modulation arrangement, as useful in OFDM wireless communications as contemplated for IEEE 802.11 wireless networking. The data flow in this approach is also analogous to Discrete Multitone modulation (DMT) as used in conventional DSL communications, as known in the art. It is contemplated that this generalized arrangement is provided by way of context only. In the system of FIG. 3, only one direction of transmission (from transmitting transceiver 10 over transmission channel C to receiving transceiver 20) is illustrated. It will of course be understood by those skilled in the art that data will also be communicated in the opposite direction, in which case transceiver 20 will be the transmitting transceiver and transceiver 10 the receiving transceiver.

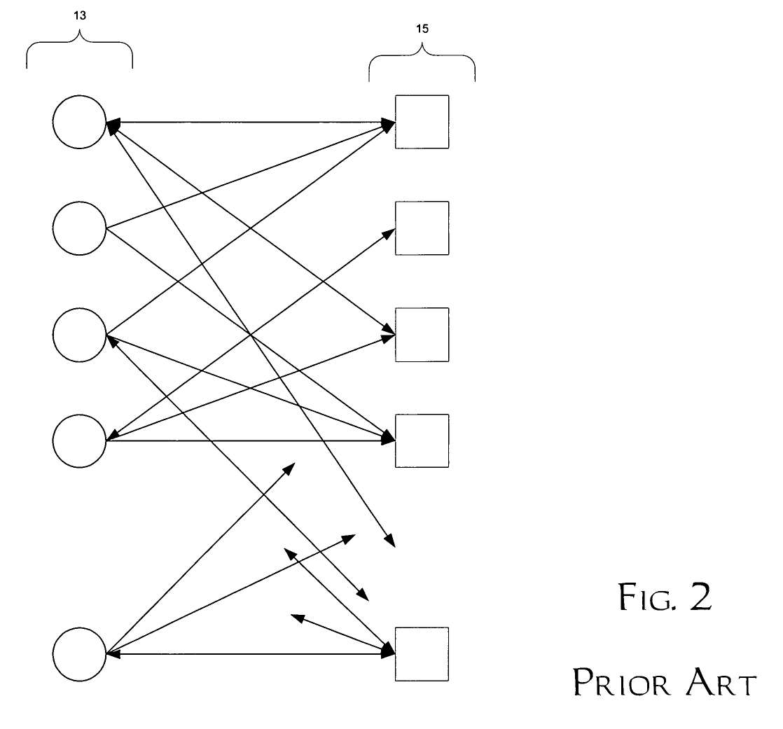

As shown in FIG. 3, transmitting transceiver 10 receives an input bitstream that is to be transmitted to receiving transceiver 20. Typically, this input bitstream is a serial stream of binary digits, in the appropriate format as produced by the data source. The input bitstream is received by FECC encoder function 11, which digitally encodes the input bitstream by applying a redundant code for error detection and correction purposes. According to this embodiment of the invention, the redundant FECC code applied by encoder function 11 is a conventional parallel concatenated convolutional code (PCCC), such as often referred to in the art as a “turbo” code. Alternatively, the code may also be of the class referred to as a Low Density Parity Check (LDPC) code, such as described above relative to FIG. 2. Many examples of these and other codes suitable for use in connection with this invention are known in the art. After application of the FECC code, bit to symbol encoder function 12 groups the incoming bits into symbols having a size, for example, ranging up to as many as fifteen bits. These symbols will modulate the various subchannels in the OFDM broadband transmission.

The encoded symbols are then applied to inverse Discrete Fourier Transform (IDFT) function 14, which associates each input symbol with one subchannel in the transmission frequency band, and generates a corresponding number of time domain symbol samples according to an inverse Fourier transform. The resulting time domain symbol samples are then converted into a serial stream of samples by parallel-to-serial converter 16. Filtering and conversion function 18 then processes the datastream for transmission, by executing the appropriate digital filtering operations, such as interpolation to increase sample rate and digital low pass filter for removing image components, for the transmission. The digitally-filtered datastream signal is then converted into the analog domain and the appropriate analog filtering is then applied to the output analog signal, prior to its transmission.

The output of filter and conversion function 18 is then applied to transmission channel C, for forwarding to receiving transceiver 20. The transmission channel C will of course depend upon the type of communications being carried out. In the wireless communications context, the channel will be the particular environment through which the wireless transmission takes place. Alternatively, in the DSL context, the transmission channel is physically realized by conventional twisted-pair wire. In any case, transmission channel C adds significant distortion and noise to the transmitted analog signal, which can be characterized in the form of a channel impulse response. This transmitted signal is received by receiving transceiver 20, which, in general, reverses the processes of transmitting transceiver 10 to recover the information of the input bitstream.

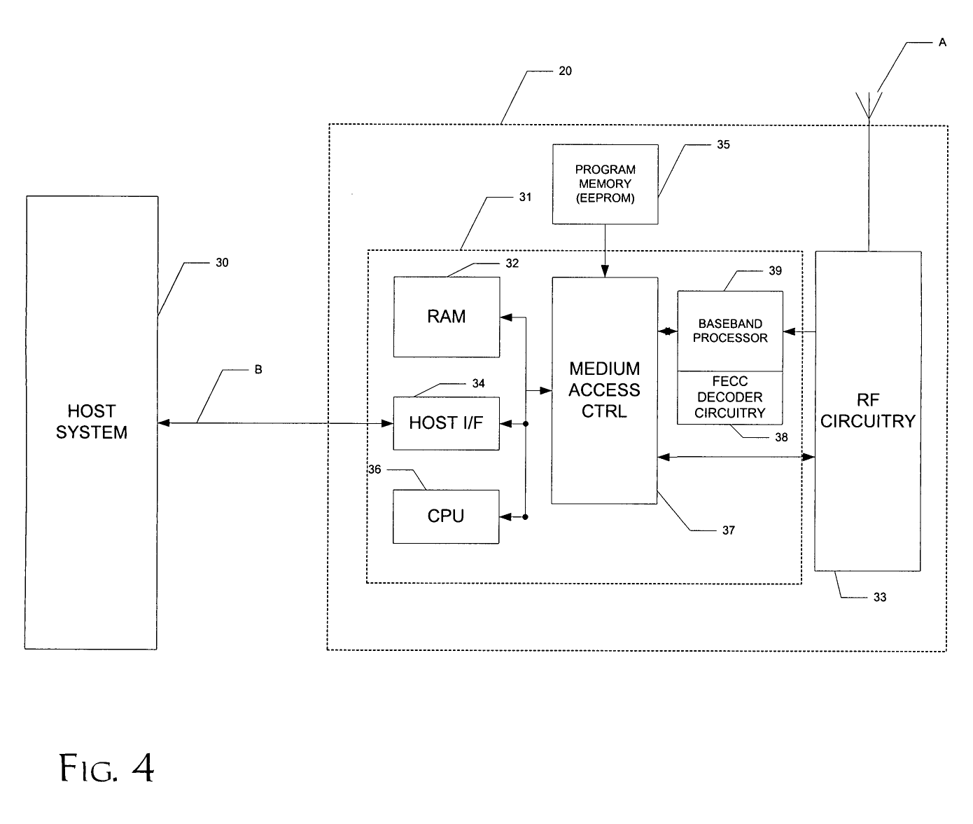

FIG. 4 illustrates an exemplary construction of receiving transceiver 20, in the form of a wireless network adapter. Transceiver 20 is coupled to host system 30 by way of a corresponding bus B. Host system 30 corresponds to a personal computer, a laptop computer, or any sort of computing device capable of wireless networking in the context of a wireless LAN; of course, the particulars of host system 30 will vary with the particular application. In the example of FIG. 2, transceiver 20 may correspond to a built-in wireless adapter that is physically realized within its corresponding host system 30, to an adapter card installable within host system 30, or to an external card or adapter coupled to host computer 30. The particular protocol and physical arrangement of bus B will, of course, depend upon the form factor and specific realization of transceiver 20.

Transceiver 20 in this example includes processor 31, which is bidirectionally coupled to bus B on one side, and to radio frequency (RF) circuitry 33 on its other side. RF circuitry 33, which may be realized by conventional RF circuitry known in the art, performs the analog demodulation, amplification, and filtering of RF signals received over the wireless channel and the analog modulation, amplification, and filtering of RF signals to be transmitted by transceiver 20 over the wireless channel, both via antenna A. The architecture of processor 31 into which this embodiment of the invention can be implemented follows that of the TNETW1130 single-chip WLAN baseband (BB) processor and medium access controller (MAC) available from Texas Instruments Incorporated. This exemplary architecture includes embedded central processing unit (CPU) 36, for example realized as a reduced instruction set (RISC) processor, for managing high level control functions within processor 31. For example, embedded CPU 36 manages host interface 34 to directly support the appropriate physical interface to bus B and host system 30. Local RAM 32 is available to embedded CPU 36 and other functions in processor 31 for code execution and data buffering. Medium access controller (MAC) 37 and baseband processor 39 are also implemented within processor 31 according to the preferred embodiments of the invention, for generating the appropriate packets for wireless communication, and providing encryption, decryption, and wired equivalent privacy (WEP) functionality. Program memory 35 is provided within transceiver 20, for example in the form of electrically erasable/programmable read-only memory (EEPROM), to store the sequences of operating instructions executable by processor 31, including the coding and decoding sequences according to the preferred embodiments of the invention, which will be described in further detail below. Also included within wireless adapter 20 are other typical support circuitry and functions that are not shown, but that are useful in connection with the particular operation of transceiver 20.

According to the preferred embodiments of the invention, FECC decoding is embodied in specific custom architecture hardware associated with baseband processor 39, and shown as FECC decoder circuitry 38 in FIG. 4. FECC decoder circuitry 38 is custom circuitry for performing the decoding of received data packets according to the preferred embodiments of the invention. Examples of the particular construction of FECC decoder circuitry 38 according to the preferred embodiment of this invention will be described in further detail below.

Alternatively, it is contemplated baseband processor 39 itself, or other computational devices within transceiver 20, may have sufficient computational capacity and performance to implement the decoding functions described below in software, specifically by executing a sequence of program instructions. It is contemplated that those skilled in the art having reference to this specification will be readily able to construct such a software approach, for those implementations in which the processing resources are capable of timely performing such decoding.

This example of transceiver 20, in the form of a wireless network adapter as described above, is presented merely by way of a single example. This invention may be used in a wide range of communications applications, including wireless telephone handsets, moderns for broadband data communication, network infrastructure elements, disk drive controllers, and the like. The particular construction of a receiver according to this invention will of course vary, depending on the application and on the technology used to realize the receiver.

Referring back to the functional flow of FIG. 3, filtering and conversion function 21 in receiving transceiver 20 processes the signal that is received over transmission channel C. Function 21 applies the appropriate analog filtering, analog-to-digital conversion, and digital filtering to the received signals, again depending upon the technology of the communications. In the DSL context, this filtering can also include the application of a time domain equalizer (TEQ) to effectively shorten the length of the impulse response of the transmission channel H. Serial-to-parallel converter 23 converts the filtered datastream into a number of samples that are applied to Discrete Fourier Transform (DFT) function 24, which recovers the symbols at each of the subchannel frequencies and outputs a frequency domain representation of a block of transmitted symbols, but including the frequency-domain response of the effective transmission channel. Recovery function 25 effectively divides out the frequency-domain response of the effective channel, for example by the application of a frequency domain equalizer (FEQ), to produce the modulating symbols. Symbol-to-bit decoder function 26 then demaps the recovered symbols, and applies the resulting bits to FECC decoder function 28.

FECC decoder function 28 reverses the encoding that was applied in the transmission of the signal, to recover an output bitstream that corresponds to the input bitstream upon which the transmission was based. As will be described in further detail below according to the preferred embodiments of this invention, FECC decoder function 28 operates in an iterative manner. Upon reaching a termination criterion for the iterative decoding, FECC decoder function 28 forwards an output bitstream, corresponding to the transmitted data as recovered by receiving transceiver 20, to the host workstation or other recipient.

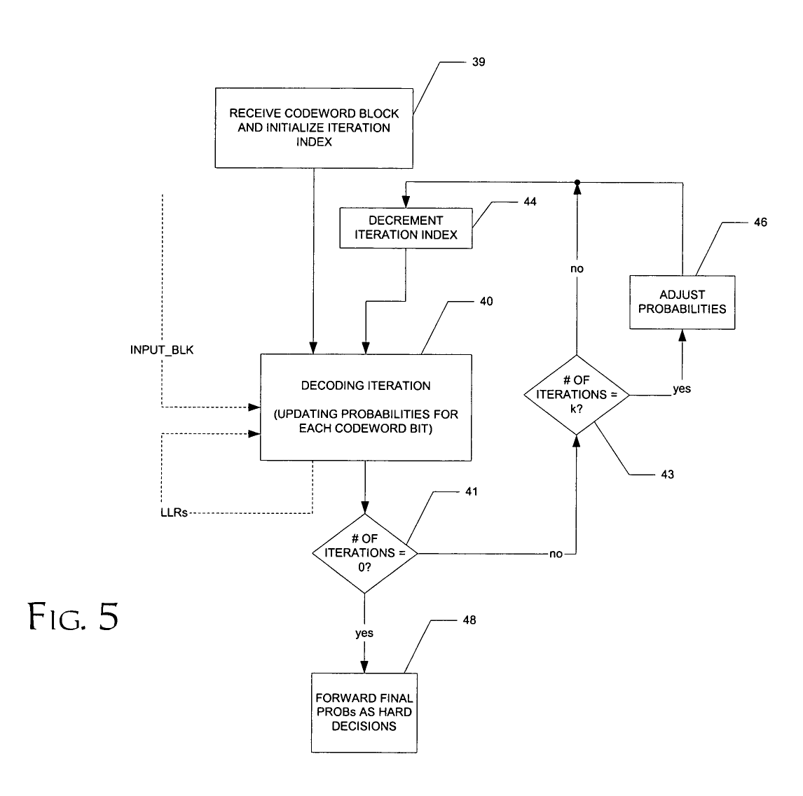

Referring now to FIG. 5, the general operation of FECC decoder function 28 according to the preferred embodiments of the invention will now be described. Those skilled in the art will recognize that this generalized description is applicable to a wide range of codes, including PCCC turbo codes, LDPC codes (e.g., as shown in FIG. 2), and other codes that can be decoded by iterative techniques. It is further contemplated that these codes include codes for which the iterative decoding alternates between decoding operations in successive iterations (such as in turbo codes) or that iteratively perform the same operations in updating the probabilities for each codeword bit (such as LDPC codes).

It is contemplated that the process of FIG. 5 in general, and the specific preferred embodiments of the invention, can be readily implemented into specific custom architecture hardware, such as the example of FECC decoder circuitry 38 associated with baseband processor 39 in FIG. 4. Alternatively, it is contemplated that these embodiments of the invention can also be realized by software routines executed by programmable digital circuitry, such as a DSP or a general purpose microprocessor. And it is further contemplated that those skilled in the art having reference to this specification will be readily able to implement these preferred embodiments of the invention, and alternative realizations to these exemplary embodiments, in such custom hardware, software, or combination of the two.

As shown in FIG. 5, the decoding operation begins with process 39, in which FECC decoder function 28 receives a codeword block after demodulation, and such preliminary decoding as required to resolve a block of codeword bits, encoded according to the FECC code applied in transmission. In the example of FIG. 4, the codeword block received in process 39 has been demodulated by DFT function 24, and initial reliability estimates for decoded bits have been generated, incorporating estimates of the channel state via FEQ 25 and demapping by symbol-to-bit decoder 26. In this example, the last remaining decoding required to recover the actual transmitted data is the decoding of the FECC, as shown in FIG. 5.

Along with receipt of the codeword block in process 39, an iteration index is initialized. According to the preferred embodiments of the invention, the termination criterion for the iterative decoding is simply a count of the number of decoding iterations performed. This constraint on the decoding process provides reasonable bit error rate performance, while controlling decoding delay (latency) and ensuring reasonable complexity in the decoding circuitry and software. In this generalized example, the iteration index is initialized to a selected count value, and the process will count down from this value to the terminal count of zero; of course, one may equivalently initialize the index to zero and increment the index until reaching the terminal value.

In process 40, a first decoding iteration is performed by FECC decoder function 28. The particular inputs and outputs of decoding iteration process 40 will, of course, depend on the particular code. As shown in FIG. 5, in the general case, decoding iteration process 40 may receive the original codeword block (line INPUT_BLK). Decoding iteration process 40 will also use, in each iteration, a set of probabilities for each of the codeword bits (these probabilities shown on lines LLRs in FIG. 5) that were produced in a previous iteration. For the first decoding iteration, of course, these probabilities will be initialized to some value, typically a neutral value. For some codes, the original codeword block input is used in each decoding iteration; in other codes, the original input is not used. The particular form of the probability information can also vary from code to code, and with the particular operation of FECC decoder function 28. In each case, however, the probability information will include an indication of the likely value for each bit, and an indication of the probability that the bit has that likely value. As suggested by FIG. 5, log-likelihood-ratios (LLRs) are preferred, as the LLR is a single value that communicates both the likely data state and the probability of that data state.

Following decoding iteration process 40, decision 41 is executed to determine whether the termination criterion has been reached. In this example, the termination criterion is the iteration index reaching zero; if not (decision 41 is NO), control passes to decision 43. In decision 43, FECC decoding function 28 determines whether the current iteration index value is equal to one or more preselected values k at which probability adjustment process 46 is to be performed. If not (decision 43 is NO), the iteration index is decremented in process 44, and another instance of decoding iteration process 40 is performed.

According to the preferred embodiment of the invention, the probabilities for some codeword bits are amplified near the end of the iterative decoding process, for example, prior to the last iteration (or, perhaps prior to the last two, or few, iterations) before reaching the termination criterion. In a general sense, probability-based iterative FECC decoding involves two values for each codeword bit: the probability that the bit is a 0 or a 1 (the reliability value), and which data value (0 or 1) is more likely for that bit. Each decoding iteration updates the reliability value for each codeword bit, based on the values for every other bit that is involved in a checksum-type equation that contains the codeword bit to be updated. In the wireless LAN implementation of this embodiment of the invention, every bit in the codeword must be correct, after decoding, to avoid a block error that causes rejection of the received block (and its retransmittal). This invention thus takes advantage of those codeword bits that have sufficiently high reliability values (probabilities) that the one or few remaining iterations will not cause the data value of the bit to change; if these selected codeword bits are already at incorrect data values, the number of remaining iterations are not sufficient to correct their data values. According to this preferred embodiment of the invention, the reliability values for those codeword bits are artificially increased, for example to certainty. These amplified probabilities will accelerate convergence of the other codeword bits in the remaining iteration or iterations, without increasing the likelihood of error in the decoded block (again, if a codeword bit for which the reliability value is amplified is already incorrect, by definition it would have remained incorrect throughout the remaining iterations even if its reliability were not amplified).

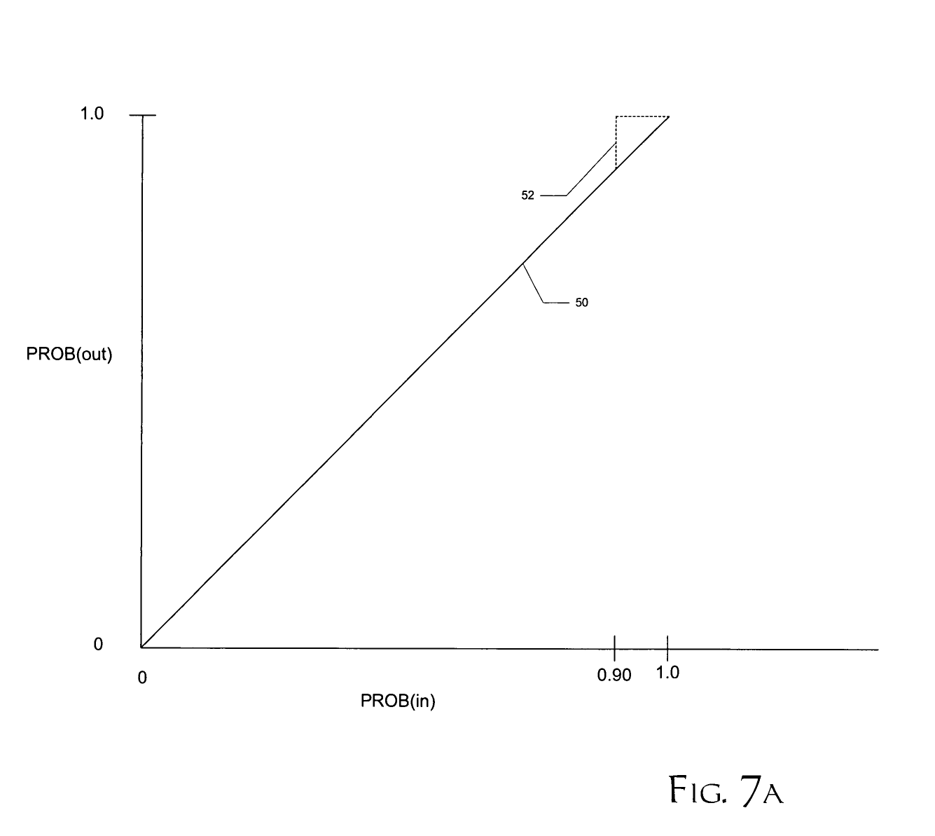

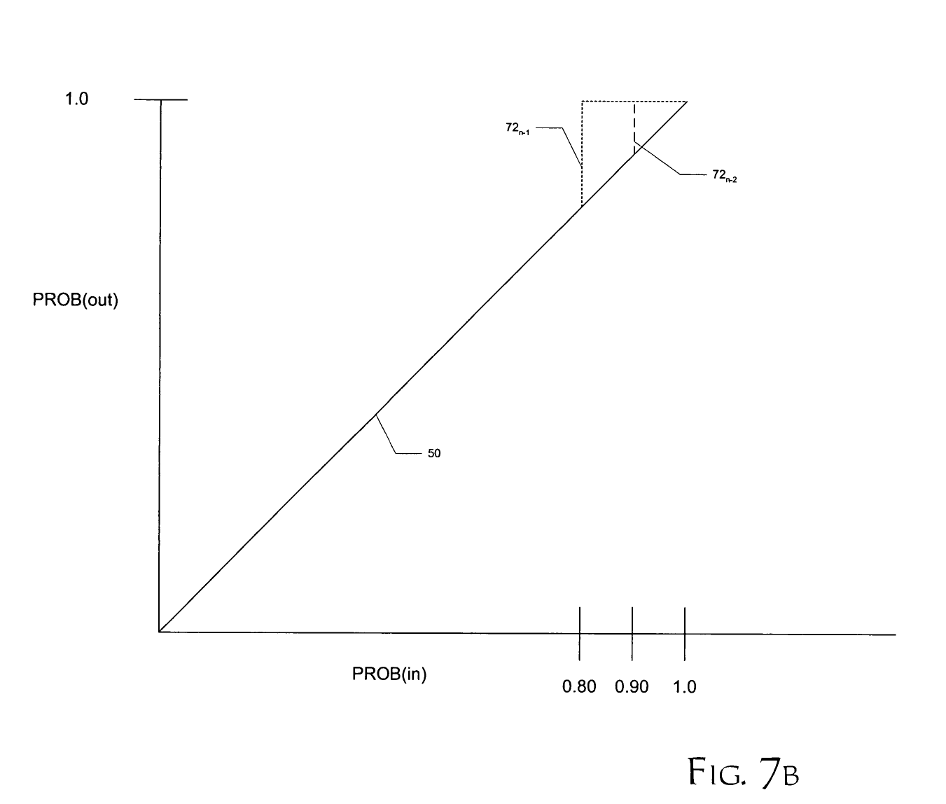

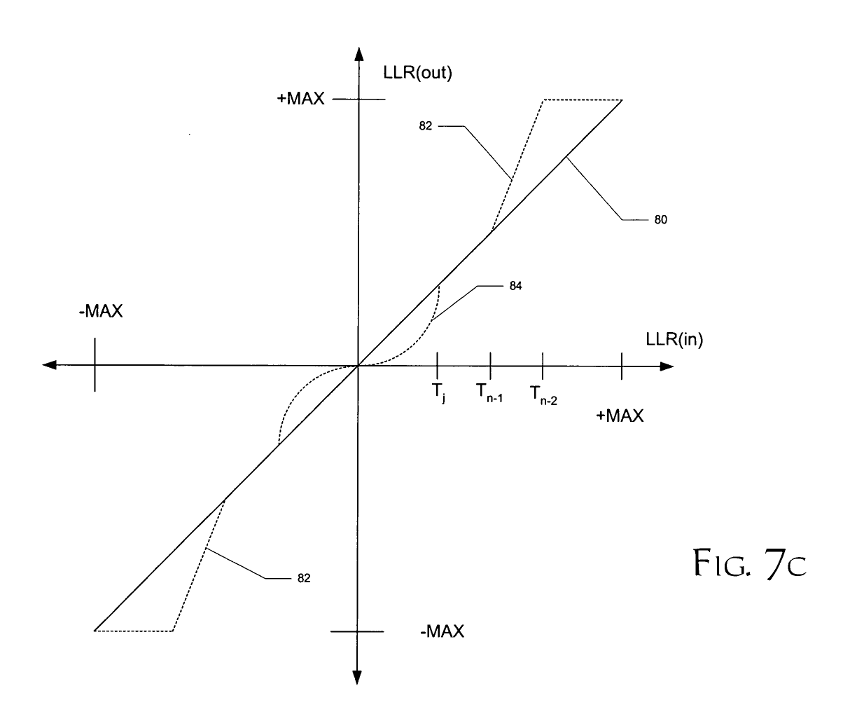

Referring back to FIG. 5, a preferred embodiment of the invention can be implemented in a straightforward manner by adjusting the probabilities for the last decoding iteration, i.e., by setting k equal to one. In this embodiment of the invention, upon decision 43 determining that the iteration index is equal to k=1 (decision 43 is YES). process 46 is then performed to adjust the probabilities for those codeword bits having already high likelihoods. FIG. 7a illustrates an example of adjustment process 46 according to this preferred embodiment of the invention.

FIG. 7a is a plot of probability values prior to process 46, along the x-axis of PROB(in), versus probability values after process 46, along the y-axis of PROB(out). In general, probability adjustment process 46 identifies a threshold probability, and adjusts the probabilities for all codeword bits having a probability above that threshold to 1.0 (i.e., certainty, or “full reliability”); this adjustment is performed regardless of the predicted data state (i.e., for both “0” and “1” predicted data values). In the example of FIG. 7a, line 50 illustrates the case in which no adjustment is made; PROB(out)=PROB(in) along line 50. But in this example, process 46 uses a probability threshold of 0.90. Any codeword bit having a probability of 0.90 or higher (for either “0” or “1”) has its probability adjusted, in process 46, to a value of 1.0, as shown by plot 52. This adjustment is based on the assumption that any codeword bit having a probability of 90% or higher will not have its data state changed in the last decoding iteration 40; in other words, even if such a codeword bit with 90% or higher probability has been decoded to the wrong data value, it will remain wrong after the last iteration. Adjusting the probabilities for these codeword bits to the full reliability value will thus have the effect of moving the probabilities for less-likely codeword bits closer to full reliability, accelerating convergence without impacting the likelihood of an error (if an adjusted bit is at the wrong data state before adjustment, it will remain wrong regardless of whether its probability is adjusted; if an adjusted bit is at the correct data state before adjustment, it remains so after adjustment). Downstream processing, such as by way of a sophisticated cyclic redundancy check (CRC), is typically performed in LAN-like applications, to ensure that there are no bit errors whatsoever in the block after decoding; if so, the block is rejected.

After the probabilities are adjusted in process 46, in this example, the iteration index is decremented to zero in process 44. The last decoding iteration is performed in process 40, following which decision 41 determines that the index is zero (decision 41 is YES). Process 48 is then performed to produce the final codeword, by using the final probability values as “hard” decisions (each codeword bit is set to its more likely binary value, regardless of the probability for that result). The resulting codeword is then forwarded on to the host system (preferably after a final CRC check as mentioned above) as the final result.

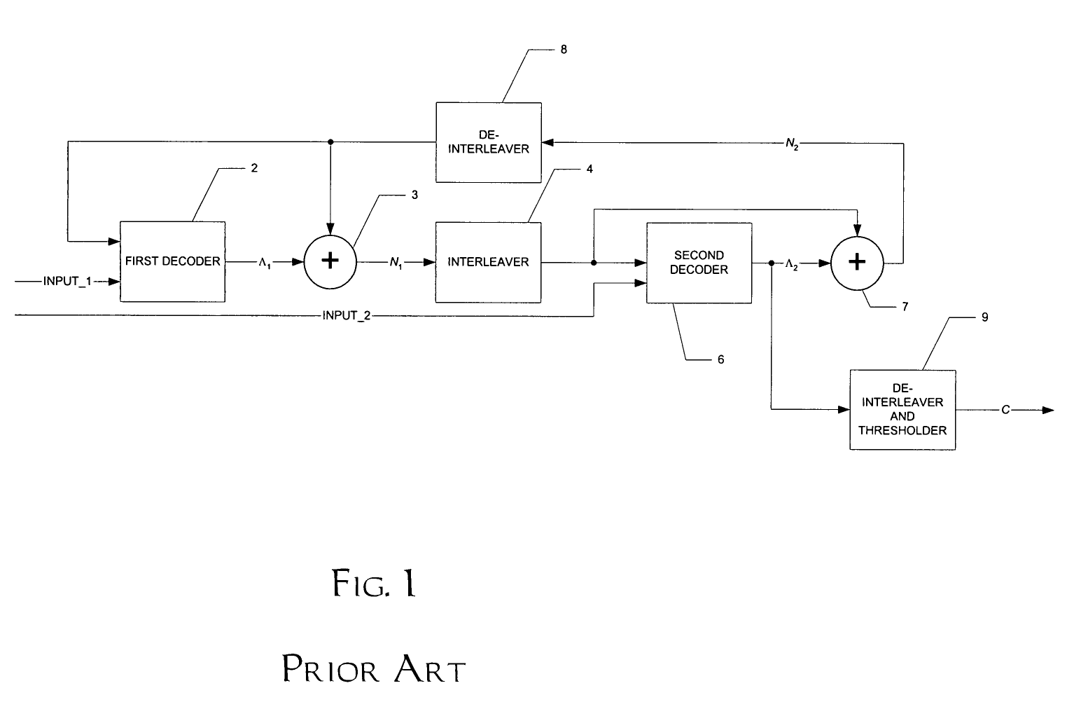

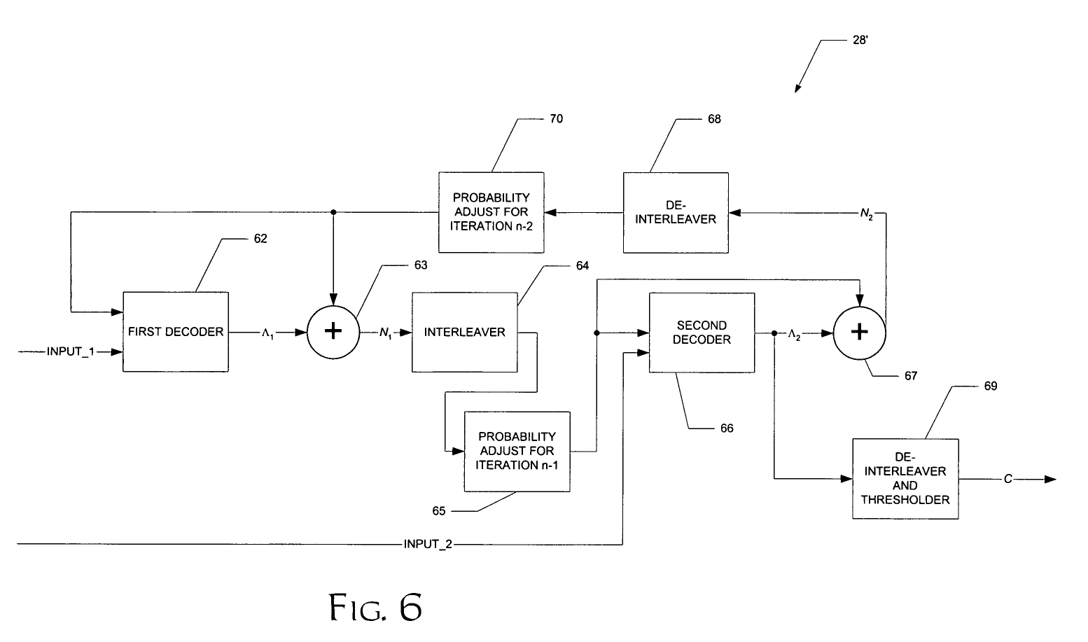

FIG. 6 illustrates an implementation of the preferred embodiment of the invention, applied to a turbo decoding realization by way of turbo decoder FECC function 28′. As in the conventional decoder of FIG. 1, encoded inputs are received on lines INPUT_1, INPUT_2, corresponding to the two encodings of the transmitted data block concatenated at the transmitter, and separated at the receiver prior to the decoding of FIG. 6. First encoding INPUT_1 is applied to first decoder 62, and second encoding INPUT_2 is applied to second decoder 66. Decoders 62, 66 are preferably maximum a posteriori (MAP) decoders, as known in the art, each of which communicates its results as a set of a posteriori probabilities Λ₁, Λ₂, respectively, in the form of LLRs. Decoder 62 generates its a posteriori output probabilities Λ₁ based upon first encoding input INPUT_1 and a priori probabilities generated by second decoder 66; conversely, decoder 66 generates its output probabilities Λ₂ based upon second encoding input INPUT_2 and a priori probabilities generated by first decoder 66.

In each case, the a priori probabilities used by each of decoders 62, 66 are subtracted from the resulting a posteriori output probabilities Λ₁, Λ₂, respectively, at summers 63, 67. As well known in the art, this subtraction reduces the positive feedback effect of the a priori probabilities on the results in future iterations. The output probabilities N₁ from summer 63 are interleaved by interleaver 64 according to the same interleaving as applied in the turbo encoding; similarly, the output probabilities N₂ from summer 67 are de-interleaved by de-interleaver 68, to align with the codeword bit positions at first decoder 62. Turbo decoder 28′ of FIG. 6 is thus an iterative decoder, with the probabilities from each decoder 62, 66 used as a priori probability values for the next decoding iteration by the other decoder 66, 62, respectively.

Upon reaching the termination criteria, the output of turbo decoder 28′ is generated by de-interleaver and thresholder 69. The resulting codeword C from function 69 is constructed from hard decisions for each of the codeword bits, based on the a posteriori output probabilities Λ₂ from the final iteration that are applied to de-interleaver and thresholder function 69.

As mentioned above relative to the general case of FIG. 5, it is contemplated that turbo decoder 28′ of FIG. 6 can be readily implemented into specific custom architecture hardware, or realized by software routines executed by programmable digital circuitry such as a DSP or a general purpose microprocessor, depending on the application and the particular design architecture.

According to the preferred embodiment of the invention, probability adjustment functions 65, 70 are inserted into iterative turbo decoder 28′ of FIG. 6. These probability adjustment functions 65, 70 serve to adjust the codeword bit probabilities in order to accelerate convergence, as described above relative to process 46 of FIG. 5. It is contemplated that either or both of functions 65, 70 in iterative turbo decoder 28′ of FIG. 6 can be used, depending upon the particular adjustment that is desired.

For example, the adjustment approach of FIG. 7a can be readily implemented into turbo decoder 28′ by the operation of probability adjustment function 65; adjustment function 70 would be skipped (or apply no adjustment) in this case. In this example, each iteration corresponds to a decoding by one of decoders 62, 66 in turbo decoder 28′; as such, the termination criterion is the execution of an even number n of decoding iterations. In this example, turbo decoder 28′ iteratively operates first decoder 62 upon first encoding input INPUT_1 and the a priori probabilities from second decoder 66 (via summer 67 and de-interleaver 68; adjustment function 70 being disabled in this case); the a posteriori probabilities Λ₁ produced by first decoder 62 in an iteration are processed by summer 63 and interleaver 64, and applied to second decoder 66 with second encoding input INPUT_2. A controller or other circuit (not shown) maintains a count or index of the number of iterations executed, in this embodiment of the invention, up to a terminal count n. Prior to the iteration index reaching the value n-1, probability adjust function 65 has no effect on the probabilities that are circulating around turbo decoder 28′.

Upon the iteration count reaching the value n-1, the overall decoding lacks only the final decoding iteration to be applied by second decoder 66. According to this embodiment of the invention, probability adjustment function 65 then operates to adjust the codeword bit probabilities according to the desired adjustment function. In this example, in which the adjustment follows plot 52 of FIG. 7a, probability adjustment function 65 identifies all codeword bits having a probability above the threshold (e.g., 0.90 as shown in FIG. 7a), for either a “0” or a “1” state, and sets the probabilities for those identified codeword bits to 1.00, or full reliability. Probabilities below the threshold are not adjusted by function 65. Second decoder 66 then uses the adjusted probabilities in its final decoding iteration, following which de-interleaver and thresholder 69 generates the output codeword C as hard decisions for each of the codeword bits, based on the a posteriori output probabilities Λ₂ from the last pass through second decoder 66.

As shown in FIG. 6, probability adjustment function 70 may also be inserted into the loop of turbo decoder 28′, for applying additional probability adjustments in multiple iterations of the decoding process. In this example in which the terminal number of iterations through turbo decoder 28′ is n, probability adjustment function 70 operates prior to the second-to-last iteration (iteration n-2), and probability adjustment function 65 operates prior to the last iteration (iteration n-1) as described above.

In adjusting probabilities in multiple iterations, according to this embodiment of the invention, the thresholds and adjustments are preferably selected based on the stage of the decoding (i.e., how many iterations remain), and also by considering the possibility that the data value of the corresponding codeword bit could change state. For example, it is preferred to have a higher threshold for adjustment at iteration n-2 than at iteration n-1. An example of this multiple-iteration adjustment approach is illustrated in FIG. 7b.

In this example, probability adjustment function 70 adjusts (to the full reliability value of 1.0) those codeword bit probabilities that are at 0.90 or higher, prior to the next-to-last iteration n-2. This adjustment is illustrated in FIG. 7b by plot 72ₙ₋₂. The basis for this adjustment is that any codeword bit with a probability higher than 90% will not be changed to a different data state over the last two decoding iterations. Prior to the last iteration n-1, probability adjustment function 65 applies its adjustment function, which may or may not be at the same threshold as that applied by function 70. In the example of FIG. 7b, a lower threshold (e.g., 0.80) is applied by probability adjustment function 65 prior to the last decoding iteration than was applied by function 70 prior to the next-to-last iteration, as shown by plot 72ₙ₋₁.

In operation according to this example of FIG. 7b, the initial iterations of turbo decoder 28′ proceed in the usual manner, with neither of adjustment functions 65, 70 becoming involved. Prior to the next-to-last decoding iteration n-2, to be performed by first decoder 62, probability adjustment function 70 operates to adjust the probabilities of those codeword bits having probabilities above 0.90, to the full reliability value of 1.0 prior to their application as a priori probabilities to first decoder 62. And as shown in FIG. 6, it is these adjusted probabilities from probability adjustment function 65 that are applied to summer 63, for subtraction of the a priori probabilities from the result of first decoder 62, as described above.

Following the decoding by first decoder 62, using the adjusted a priori probabilities from function 70, and after subtraction of these adjusted a priori values at summer 63 and interleaving by interleaver 64, probability adjustment function 65 operates to further adjust the probabilities for the last iteration n-1 to be executed by second decoder 66. In this example of FIG. 7b, probability adjustment function 65 adjusts the probabilities of those codeword bits having probabilities above 0.80 to the full reliability value of 1.0. These adjusted probabilities are forwarded to second decoder 66 for use in this final decoding iteration. The resulting output of second decoder 62, after this last iteration, is then forwarded to de-interleaver and thresholder function 69 for hard decisions, and forwarding as codeword C.

In each of the preferred embodiments of the invention described above relative to FIGS. 7a and 7b, the probability adjustment is applied as “pegging” probabilities to their full reliability values, for those codeword bits having probabilities above a certain threshold or thresholds. This adjustment is performed in response to the number of iterations remaining in the iterative decoding process, as evident from this description. It is contemplated that this adjustment of the probabilities will accelerate convergence to a usable decoding result, within a reasonable number of iterations. Accordingly, it is contemplated that the tradeoffs among code performance, code latency or delay, and decoder complexity can be greatly eased by implementation of the accelerated convergence techniques according to this invention.

Various alternatives in the iteration-dependent probability adjustment according to the preferred embodiments of the invention are also contemplated. For example, it is contemplated that the adjustment of the probabilities need not place the adjusted threshold at the full reliability value. Indeed, it is contemplated that the probability adjustment need not adjust the probabilities to a more certain value, but instead may adjust the probabilities to a less certain value. Some of these alternative approaches will now be described relative to FIG. 7c.

FIG. 7c illustrates plots of one or more probability adjustment functions, as applied to probabilities in LLR form, i.e., as signed values between a minimum value −MAX and a maximum value +MAX. As mentioned above and as well known, the sign of an LLR value is indicative of the likely data state (negative LLR corresponding to a likely “1” state, and a positive LLR corresponding to a likely “0” state). Plot 80 illustrates the relationship for non-adjusted probabilities, which of course is a line corresponding to the adjusted probability LLR(out) equal to the incoming probability LLR(in).

As shown in FIG. 7c, plots 82 illustrate a probability adjustment having two threshold values Tₙ₋₂ and Tₙ₋₁. Plots 82 apply a linearly increasing probability value to any probability above threshold Tₙ₋₁; for probability values at or above threshold Tₙ₋₂, the probability is adjusted to the full reliability value (±MAX, depending on the binary value). The thresholds Tₙ₋₂ and Tₙ₋₁ may be applied to different iterations (e.g., to next-to-last iterations n-2, n-1, respectively), or may both be applied at the same iteration or iterations, as desired by the designer. The linearly increased probabilities between thresholds Tₙ₋₁ and Tₙ₋₂ may be advantageous in some cases, by still accelerating convergence, but still allowing for the possibility that a high probability codeword bit could change data states in later iterations.

According to another alternative embodiment of the invention, the adjustment in probability may be decreased. This alternative approach is illustrated by plot 84, in which LLR probability values below ±Tⱼ are reduced to a lower likelihood value, along a non-linear curve. Indeed, as the incoming probability values LLR(in) approach equal likelihood, the adjustment of plot 84 forces the adjusted values LLR(out) closer to zero. It is contemplated that this reducing of probabilities may further accelerate convergence by permitting those codeword bits that have relatively poor confidence to be more easily corrected by later decoding iterations. Further in the alternative, it is contemplated that the adjustment of plot 84 may be more beneficial if applied earlier in the iterative decoding, for example in the first one or few decoding iterations, so that the ambivalent codeword bits have time to converge. Again, the probability adjustment of plot 84 remains subject to the remaining number of iterations in the iterative decoding, in order to best take advantage of the ability of the iterative decoding to converge upon a valid codeword result.

As evident from this description, the various alternatives in the slope or nature of the probability adjustment (i.e., hard setting to a fixed value, linear adjustment, non-linear adjustment), in the iterations at which the adjustment are applied, and the direction of the adjustment, can be used in any combination desired by the designer of the iterative decoder. And further in the alternative, as mentioned above, it is contemplated that the probability adjustment according to this invention can be applied not only to turbo decoding, but to any iterative decoding operation, including LDPC decoding, iterative decoding of concatenated Reed-Solomon and convolutional codes, and the like.

According to this invention, therefore, important advantages in the design and operation of an iterative decoder are attained. By adjusting the probability values during decoding, utilizing the number of iterations remaining in the decoding (or number of iterations performed so far), it is contemplated that convergence to an accurate decoded result can be accelerated, requiring fewer iterations for a given performance level. This reduction in the number of iterations corresponds to a reduced decoding delay, or latency, for a given decoder complexity. The difficult tradeoffs required of the decoder designer are thus substantially eased by this invention, resulting in excellent bit error rates, with minimal decoding delay, and at low decoder cost.

While the present invention has been described according to its preferred embodiments, it is of course contemplated that modifications of, and alternatives to, these embodiments, such modifications and alternatives obtaining the advantages and benefits of this invention, will be apparent to those of ordinary skill in the art having reference to this specification and its drawings. It is contemplated that such modifications and alternatives are within the scope of this invention as claimed.

What is claimed is:

1. An iterative decoding method, comprising the steps of:
receiving a block of encoded data;
first applying a decoding operation to the block to produce a set of probability values, each corresponding to one of a plurality of codeword bit values;
repeating the applying step, using the set of probability values, for a predetermined number of iterations;
prior to a selected iteration of the repeated applying step, adjusting those probability values according to a probability threshold value, so that the applying step for the selected iteration uses the adjusted probability values; and
after the repeated applying step, generating a codeword output.

2. The method of claim 1, wherein a first selected iteration is the last of the predetermined number of iterations.

3. The method of claim 2, wherein the adjusting step adjusts those probability values that are above a first probability threshold value to a full reliability value.

4. The method of claim 2, wherein a second selected iteration is a next-to-last of the predetermined number of iterations.

5. The method of claim 4, wherein the adjusting step prior to the last of the predetermined number of iterations adjusts those probability values that are above a first probability threshold value to a full reliability value;
and wherein the adjusting step prior to the next-to-last of the predetermined number of iterations adjusts those probability values that are above a second probability threshold value to a full reliability value.

6. The method of claim 5, wherein the second probability value is closer to the full reliability value than is the first probability value.

7. The method of claim 1, wherein the adjusting step adjusts those probability values that are above a first probability threshold value according to an adjustment function.

8. The method of claim 7, wherein the adjustment function is a linear function.

9. The method of claim 1, wherein the adjusting step adjusts those probability values that are below a first probability threshold value to a lower reliability value.

10. The method of claim 1, wherein the decoding operation is a Low Density Parity Code message passing operation.

11. The method of claim 1, wherein the decoding operation is a convolutional code decoding operation.

12. The method of claim 11, wherein alternating iterations of the decoding operation correspond to alternating decoding operations of a parallel concatenated convolutional code.

13. A receiving apparatus for a communications network, comprising:
a network interface;
a decoding circuit, coupled to the network interface, for decoding each of successive blocks of data by performing a sequence of operations comprising:
first applying a decoding operation to the block to produce a set of probability values, each corresponding to one of a plurality of codeword bit values;
repeating the applying step, using the set of probability values, for a predetermined number of iterations;
prior to a selected iteration of the repeated applying step, adjusting those probability values according to a probability threshold value, so that the applying step for the selected iteration uses the adjusted probability values; and
after the repeated applying step, generating a codeword output; and
a host interface, coupled to the decoding circuit, for receiving the codeword output.

14. The apparatus of claim 13, wherein the decoding circuit comprises;
a programmable processor; and
program memory storing a software routine for performing the sequence of operations.

15. The apparatus of claim 13, wherein the network interface comprises:
an antenna; and
radio frequency circuitry coupled to the antenna.

16. The apparatus of claim 13, further comprising:
a demodulator, for demodulating signals received at the network interface into encoded blocks of data, for decoding by the decoding circuit.

17. The apparatus of claim 13, wherein a first selected iteration is the last of the predetermined number of iterations;
and wherein the adjusting operation adjusts those probability values that are above a first probability threshold value to a full reliability value.

18. The apparatus of claim 17, wherein a second selected iteration is a next-to-last of the predetermined number of iterations;
and wherein the adjusting operation prior to the next-to-last of the predetermined number of iterations adjusts those probability values that are above a second probability threshold value to a full reliability value.

19. The apparatus of claim 18, wherein the second probability value is closer to the full reliability value than is the first probability value.

20. The apparatus of claim 13, wherein the adjusting operation adjusts those probability values that are above a first probability threshold value according to an adjustment function.

21. The apparatus of claim 13, wherein the adjusting operation adjusts those probability values that are below a first probability threshold value to a lower reliability value.

22. The apparatus of claim 13, wherein the decoding operation is a Low Density Parity Code message passing operation.

23. The apparatus of claim 13, wherein the decoding operation is a convolutional code decoding operation.

24. The apparatus of claim 23, wherein alternating iterations of the decoding operation correspond to alternating decoding operations of a parallel concatenated convolutional code.
